(19) United States
(12) Patent Application Publication
(10) Pub. No.: US 2017/0115071 A1
(43) Pub. Date: Apr. 27, 2017

(54) HEAT DISSIPATION STRUCTURE AND WATER BLOCK HAVING THE SAME

(71) Applicant: TAIWAN MICROLOOPS CORP., New Taipei City (TW)

(72) Inventor: Chun-Hung LIN, New Taipei City (TW)

(21) Appl. No.: 14/979,850

(22) Filed: Dec. 28, 2015

(30) Foreign Application Priority Data
Oct. 26, 2015 (TW) 104217136

(51) Int. Cl. F28D 15/02; F28D 15/04; H05K 7/20

(52) U.S. Cl. CPC F28D 15/0275; H05K 7/20309; F28D 15/04

(57) ABSTRACT

A heat dissipation structure and water block having the same are provided in the present disclosure. The heat dissipation structure includes a vapor chamber and a heat dissipation component. A through opening is disposed on and through the vapor chamber, and the vapor chamber includes a heated surface. The heat dissipation component includes a base plate and multiple fins extended from the base plate, and the base plate includes a bottom surface. The heat dissipation component is configured corresponding to the through opening, and a coplanar structure is formed by the bottom surface and the heated surface. Heat conductive and heat dissipation performances of the heat dissipation structure and the water block are thereby improved.

### BACKGROUND OF THE INVENTION

Technical Field

The present disclosure is related to heat dissipation technology, and particularly related to a heat dissipation structure and water block having the same applied on heat generating electronic element.

Description of Prior Art

Heat generated by electronic components is increased as operation speed thereof rising. Heat dissipation devices or vapor chambers made of alloy of aluminum and copper are commonly applied to effectively solve the problem of high heat generation. However, the aforementioned heat dissipation structures perform poor thermal conductivity and are complicated for manufacture.

A conventional heat dissipation device comprises a base plate and fins extended from the base plate. The heat dissipation structure possesses good thermal conductivity, but is poor. Therefore, heat dissipation structures including the vapor chamber and the heat dissipation device are developed. The heat dissipation device is fixed on the vapor chamber via welding materials such as solder paste. The vapor chamber comprises an upper case and a lower case, and capillaries are disposed in a space between the upper case and the lower case. The upper case and the lower case are welded. Working fluid is filled between the upper case and the lower case. The final presses are degassed and sealing.

The conventional heat dissipation structure possesses good thermal conductivity and heat dissipation performance. However, there are following problems in actual use. Each case of the vapor chamber resists high temperature and pressure variations in the chamber, the vapor chamber therefore cannot be designed compact. Large thickness is accompanied with high thermal resistance and unfavorable heat transfer, and thermal conductivity and heat dissipation performance thereof cannot be well performed. Furthermore, welding materials between the vapor chamber and the heat dissipation device increase thermal resistances. The above disadvantages need to be improved.

### SUMMARY OF THE INVENTION

It is an object of the present invention to provide a heat dissipation structure and a water block having the structure. Particularly, thermal conductive and heat dissipation performances of present disclosure are improved via disposing a vapor chamber and a base plate simultaneously contacted with a heat source to transfer heat.

In order to achieve the aforementioned object, a heat dissipation structure is provided in the present disclosure. The heat dissipation structure is inclusive of a vapor chamber and a heat dissipation component. A through opening is disposed on and through the vapor chamber, and the vapor chamber is comprised of a heated surface. The heat dissipation component is inclusive of a base plate and a plurality of fins extended from the base plate, the base plate is comprised of a bottom surface. The heat dissipation component is configured corresponding to the through opening, and a coplanar structure is formed by the bottom surface and the heated surface.

In order to achieve the aforementioned object, a heat dissipation structure is further provided in the present disclosure. The water block is inclusive of a heat dissipation structure and a cover. The heat dissipation structure is inclusive of a vapor chamber and a heat dissipation component. A through opening is disposed on and through the vapor chamber, and the vapor chamber is comprised of a heated surface. The heat dissipation component is inclusive of a base plate and multiple fins extended from the base plate, and the base plate is inclusive of a bottom surface. The heat dissipation component is configured corresponding to the through opening, and a coplanar structure being formed by the bottom surface and the heated surface. The vapor chamber is covered by the cover, and a chamber is formed between the cover and the vapor chamber. Each fin is formed in the chamber, and a water inlet and a water outlet are opened on the cover.

The present disclosure further achieves the following effect. The basal segments are able to be made significantly thinner, thermal resistances thereof are therefore reduced, and heat could be rapidly transferred thereby. The heat dissipation component is formed in center area of the vapor chamber to contact and transfer heat from the hottest area of a heat source, and thereby rapidly dissipates heat from the heat source.

### BRIEF DESCRIPTION OF DRAWINGS

FIG. 1 is a perspective exploded view showing the heat dissipation structure of a first embodiment of the present disclosure.

FIG. 2 is a schematic view showing the heat dissipation structure of the first embodiment of the present disclosure.

FIG. 3 is a sectional view of the heat dissipation structure of the first embodiment of the present disclosure.

FIG. 4 is an exploded sectional view of the heat dissipation structure of a second embodiment of the present disclosure.

FIG. 5 is a sectional view of the heat dissipation structure of the second embodiment of the present disclosure.

FIG. 6 is an exploded sectional view of the heat dissipation structure of a third embodiment of the present disclosure.

FIG. 7 is a sectional view of the heat dissipation structure of the third embodiment of the present disclosure.

FIG. 8 is a schematic view showing the water block of the present disclosure.

### DETAILED DESCRIPTION OF EMBODIMENT

Detail descriptions and technical contents of the present disclosure are described below with drawings. However, the drawings are provided for reference and demonstration, and the present disclosure should not be limited by the drawings.

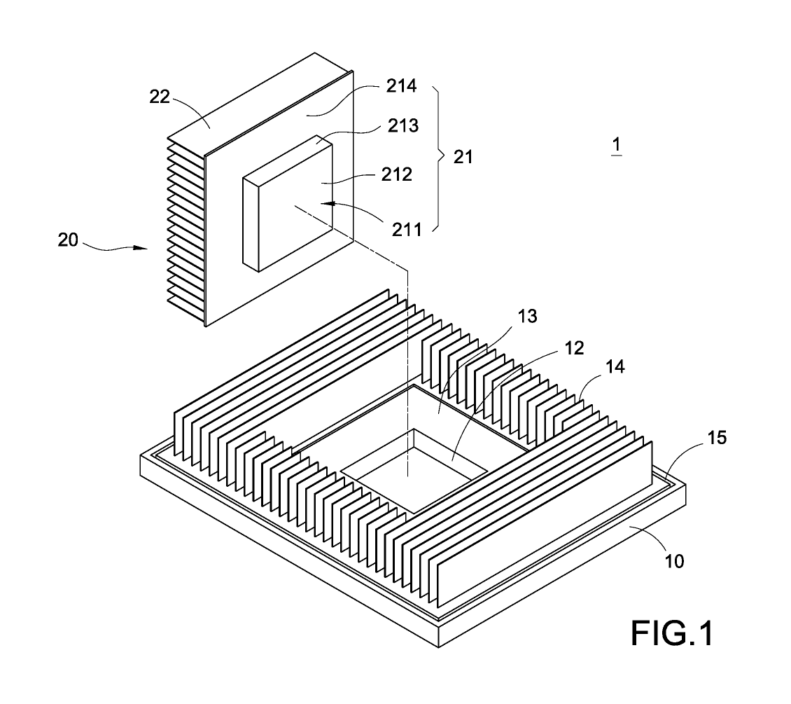

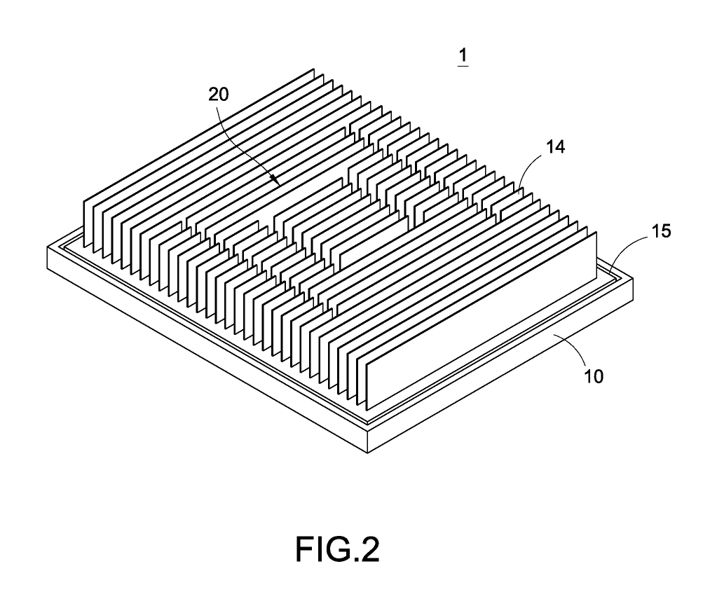

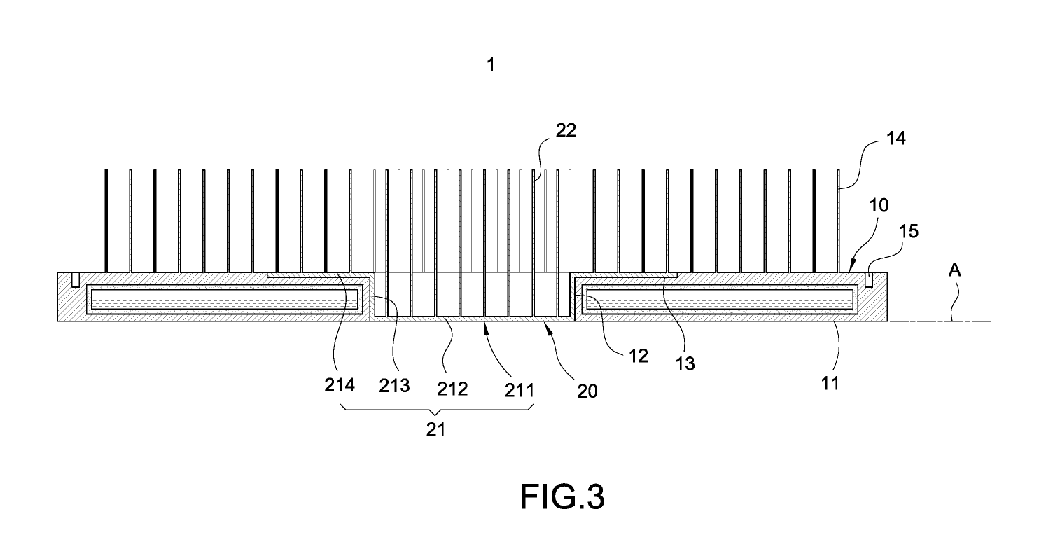

Please refer to FIG. 1 to FIG. 3. A heat dissipation structure 1 is provided in the present disclosure. The heat dissipation structure primarily comprises a vapor chamber 10 and a heat dissipation component 20.

A vacuum chamber is formed in the vapor chamber 10. Capillaries made with meshes and sintered metals and supporters constituted by helical springs or rods are disposed in the vacuum chamber. Working fluid such as water is filled in the vacuum chamber. Heat is transferred by the working fluid via vapor-liquid phase change. The vapor chamber 10 of the present embodiment is substantially a rectangular body, but shapes thereof should not be limited thereby. The vapor chamber 10 could also be a cylinder or another shapes. A heated surface 11 is formed on an external bottom of the vapor chamber 10. A through opening 12 is formed at a central area of the vapor chamber 10. An upper connecting segment 13 of step shape is arranged on top of the vapor chamber 10 at an outer periphery of the through opening 12.

Moreover, the heat dissipation structure 1 further comprises a plurality of fins 14, each fin 14 is formed at the vapor chamber 10 at the outer periphery of the upper connecting segment 13 via extrusion or skiving process, and each fin 14 could also be formed on top of the vapor chamber 10 via joint. Furthermore, an annular insert groove 15 is formed at an outer periphery of each fin 14 on top of the vapor chamber 10.

The heat dissipation component 20 could be made of copper, aluminum, or alloy thereof. The heat dissipation component 20 primarily comprises a base plate 21 of a rectangular shape and a plurality of fins 22. The base plate 21 comprises a bottom surface 211. The base plate 21 of the present embodiment primarily comprises a base segment 212, upright plate segments 213 respectively extended from opposite sides of the base segment 212 and a coupling segment 214 extended from the upright plate segment 213 and bent toward a horizontal. The aforementioned bottom surface 211 is formed on external of the base segment 212. Each fin 22 could be formed on the base segment 212 and the coupling segment 214 and arranged at interval via extrusion or skiving process.

The heat dissipation component 20 is arranged corresponding to a location of the through opening 12 of the vapor chamber 10. The through opening 12 is sealed by the base segment 212, the coupling segments 214 are respectively attached to corresponded upper connecting segment 13, and each upright plate segment 213 is attached to an internal surface of the through opening 13. A thermally conductive medium (not shown in drawings) could be used to fix the coupling segments 214 with the upper connecting segment 13 and fix the upright plate segment 213 with the upper connecting segment 13. Thereby, a coplanar structure A is formed by the bottom surface 211 of the base plate 21 and the heated surface 11. The coplanar structure A is used to be in contact with a heat source (not shown in drawings).

During an operation, the bottom surface 211 of the base plate 21 and the heated surface 211 of the vapor chamber 10 are simultaneously in contact with the heat source. A part of heat could be directly transferred to the fins 22 through the base segment 212 and dissipated. Another part of heat is rapidly transferred away via vapor-liquid phase change occurred in the vapor chamber 10, and further dissipated through each fin 14. Thereby, heat dissipation performances of the heat dissipation structure 1 are improved.

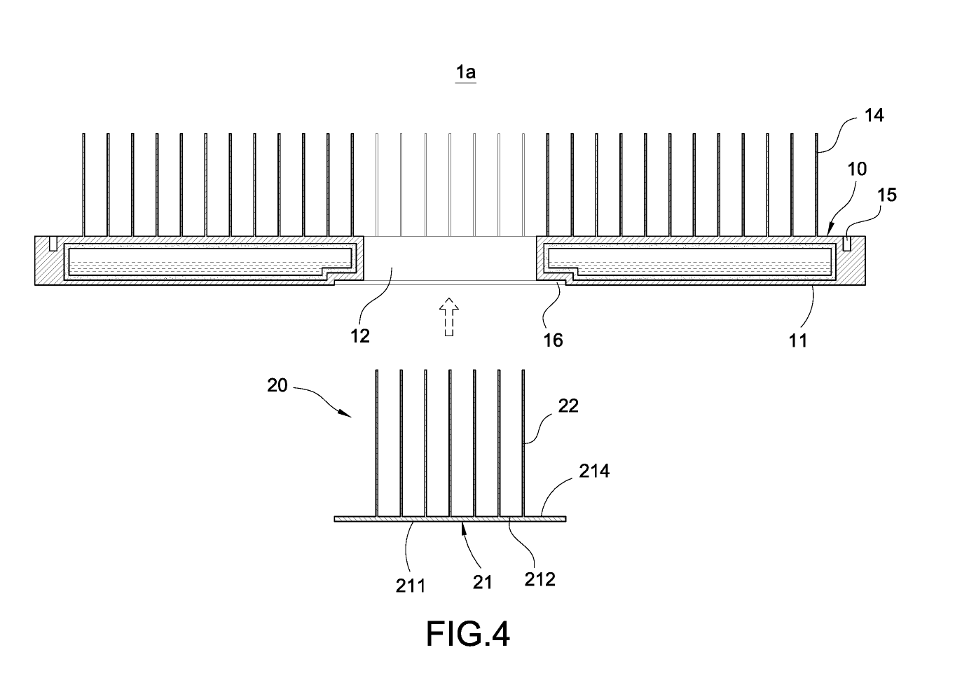

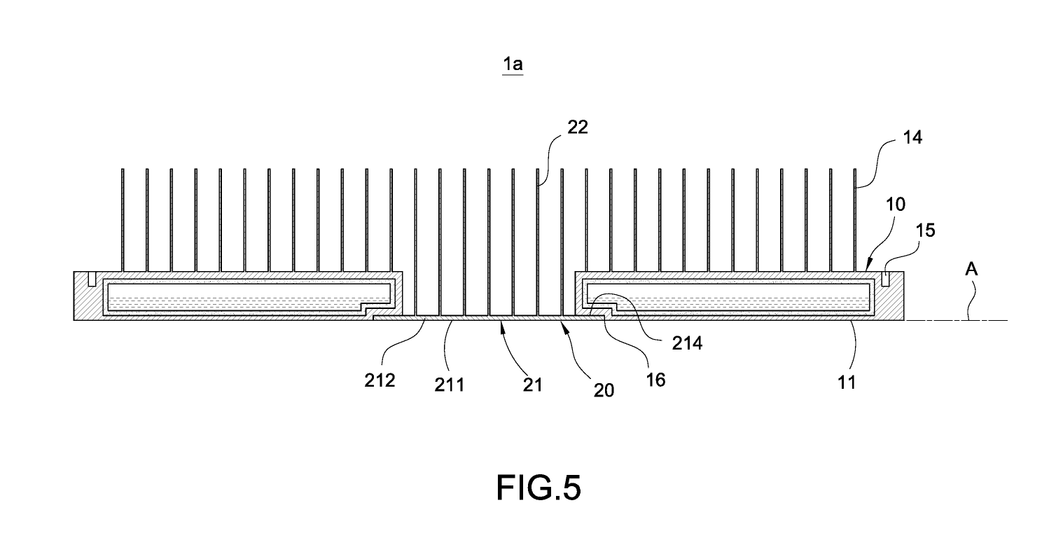

Please refer to FIGS. 4 and 5. In addition to the aforementioned embodiment of the present disclosure, according to a heat dissipation structure 1a of another embodiment, a lower connecting segment 16 of step shape is arranged on bottom of the vapor chamber 10 at the outer periphery of the through opening 12. The base plate 21 comprises a base segment 212 and coupling segments 214 respectively and horizontally extended from opposite sides of the base segment 212. The bottom end of the through opening 12 is sealed by the base segment 212. Each coupling segments 214 is respectively attached to corresponded lower connecting segment 16. The thermally conductive medium could be used to fix each coupling segments 214 with each corresponded lower connecting segment 16. Thereby, a coplanar structure A is formed by the bottom surface 211 of the base plate 21 and the heated surface 11.

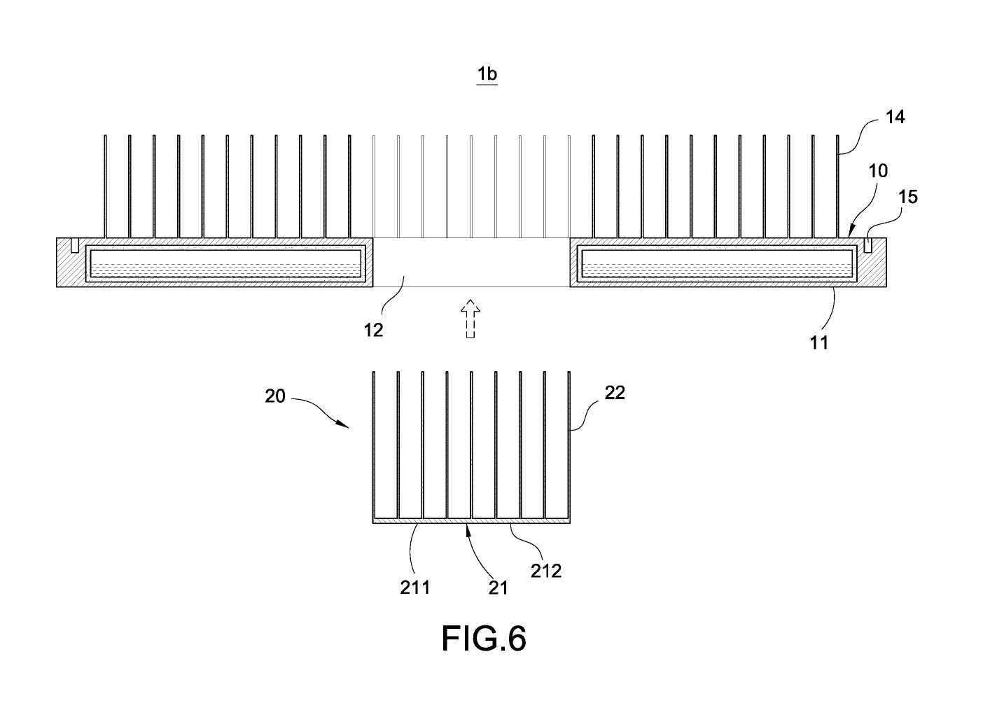

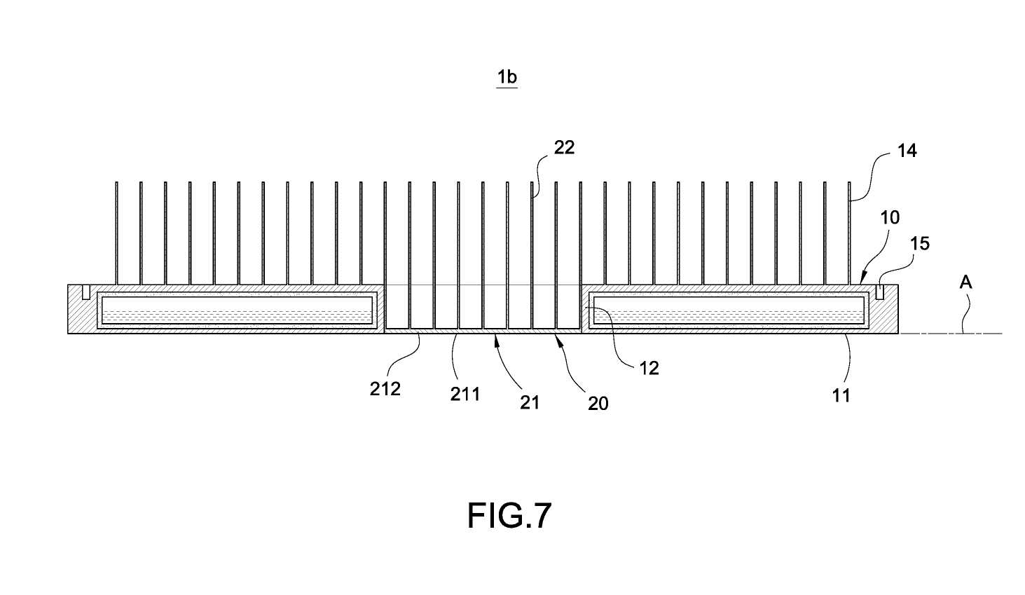

Please refer to FIGS. 6 and 7. According to a heat dissipation structure 1b of another embodiment, the bottom end of the through opening 12 is sealed by the base segment 212. The fins 22 arranged at opposite sides of the through opening 12 are attached to the internal surface of the through opening 12. The thermally conductive medium could be used to fix the fins 22 with the internal surface of the through opening 12. Thereby, a coplanar structure A is formed by the bottom surface 211 of the base plate 21 and the heated surface 11.

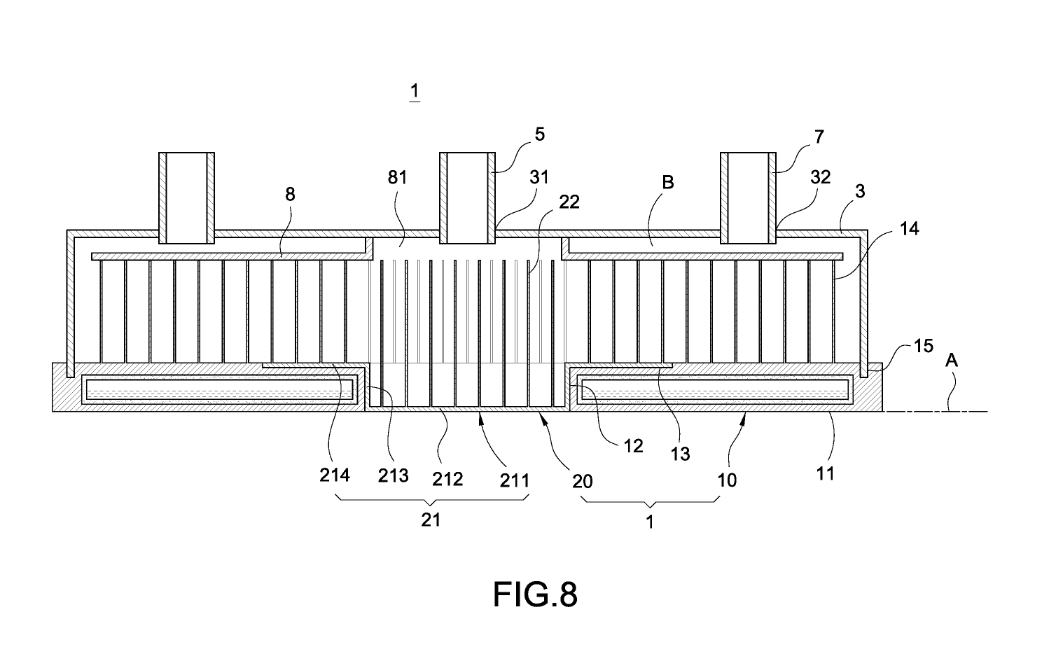

Please refer to FIG. 8. A water block having the aforementioned heat dissipation structure is provided in the present disclosure. The water block primarily comprises a heat dissipation structure 1 and a cover 3. The vapor chamber 10 is covered by the cover 3, and a bottom edge of the cover 3 is correspondingly embedded in the aforementioned insert groove 15. A chamber B is formed between the cover 3 and the vapor chamber 10, the fins 22 and the heat dissipation fins 14 are respectively formed in the chamber B, and a water inlet 31 and a water outlet 32 respectively communicated with the chamber B are opened on the cover.

In addition, the water block of the present disclosure further comprises an inlet tube 5, two outlet tube 7 and a spacer plate 8. The inlet tube 5 is connected to corresponded water inlet 31, and the outlet tubes 7 are connected to corresponded water outlet 32. The spacer plate 8 is clipped between a top end of each fin 14 and the cover 3 and clipped between a top end of each heat dissipation sin 22 and the cover 3. A fluid channel 81 is formed at center of the spacer plate 8 corresponding to the inlet tube 5. While the fluid enters the inlet tube 5, each fin 22 and each base segment 212 are directly impacted by the fluid. Primary heats are thereby brought away from each fin 22 and each base segment 212. The fluid further flows heat dissipation fins 14 at both sides and secondary heats are thereby brought away therefrom. Then, the fluid flows out through channels formed between the spacer plate 8 and top of the cover 3, and flows out through each outlet tube 7. The fluid flows in the water block as above description.

In summary, the heat dissipation structure and water the block having the structure of the present disclosure are indeed able to achieve expected purpose, and thereby improve conventional technologies. Therefore, the present disclosure is novel and inventive, and fully meets requirements of patentability. The applicant therefore filled an application according to patent law. Please review and kindly approve the present disclosure to ensure rights of the applicant.

What is claimed is:

1. A heat dissipation structure, comprising:
a vapor chamber having a through opening disposed on and through the vapor chamber, the vapor chamber having a heated surface; and
a heat dissipation component, comprising a base plate and a plurality of fins extended from the base plate, the base plate having a bottom surface, the heat dissipation component being arranged corresponding to the through opening, and a coplanar structure being formed by the bottom surface and the heated surface.

2. The heat dissipation structure according to claim 1, wherein the through opening is formed at a central area of the vapor chamber.

3. The heat dissipation structure according to claim 2, wherein an upper connecting segment is arranged on top of the vapor chamber at an outer periphery of the through opening, the base plate comprises a base segment, upright plate segments respectively extended from opposite sides of the base segment and a coupling segment extended from the upright plate segment and bent toward a horizontal direction, the bottom surface is formed on external of the base segment, a bottom end of the through opening is sealed by the base segment, each coupling segment is respectively attached to corresponded upper connecting segment.

4. The heat dissipation structure according to claim 3, wherein each upright plate segment is respectively attached to an internal surface of the through opening.

5. The heat dissipation structure according to claim 3, wherein the fins are formed on the base segment and the coupling segments and arranged at interval via extrusion or skiving process.

6. The heat dissipation structure according to claim 2, wherein the a lower connecting segment is arranged on bottom of the vapor chamber at the outer periphery of the through opening, the base plate comprises a base segment, and coupling segments respectively and horizontally extended from opposite sides of the base segment, the bottom surface is formed on external of the base segment, a bottom end of the through opening is sealed by the base segment, each coupling segment is respectively attached to corresponded lower connecting segment.

7. The heat dissipation structure according to claim 2, wherein the base plate comprises a base segment, the bottom surface is formed on outside of the base segment, a bottom end of the through opening is sealed by the base segment, and each fin is respectively attached to an internal surface of the through opening.

8. The heat dissipation structure according to claim 1, further comprising a plurality of heat dissipation fins, and the fins being formed on top of the vapor chamber and arranged at interval.

9. A water block, comprising:
a heat dissipation structure, comprising:
a vapor chamber, a through opening being disposed on and through the vapor chamber, the vapor chamber being comprised of a heated surface; and
a heat dissipation component, comprising a base plate and a plurality of fins extended from the base plate, the base plate being comprised of a bottom surface, the heat dissipation component being configured corresponding to the through opening, and a coplanar structure being formed by the bottom surface and the heated surface; and
a cover, the vapor chamber being covered thereby, a chamber being formed between the cover and the vapor chamber, each fin being formed in the chamber, and a water inlet and a water outlet are opened on the cover.

10. The water block according to claim 9, wherein the through opening is formed at a central area of the vapor chamber.

11. The water block according to claim 10, wherein an upper connecting segment is arranged on top of the vapor chamber at an outer periphery of the through opening, the base plate is comprised of a base segment, upright plate segments respectively extended from opposite sides of the base segment and a coupling segment extended from the upright plate segment and bent to be horizontal, the bottom surface is formed on external of the base segment, a bottom end of the through opening is sealed by the base segment, each coupling segment is respectively attached to corresponded upper connecting segment.

12. The water block according to claim 11, wherein each upright plate segment is respectively attached to an internal surface of the through opening.

13. The water block according to claim 11, wherein the fins are formed on the base segment and the coupling segments and arranged at interval via extrusion or skiving process.

14. The water block according to claim 10, wherein the a lower connecting segment is arranged on bottom of the vapor chamber at the outer periphery of the through opening, the base plate is comprised of a base segment and coupling segments respectively and horizontally extended from opposite sides of the base segment, the bottom surface is formed on external of the base segment, a bottom end of the through opening is sealed by the base segment, each coupling segment is respectively attached to corresponded lower connecting segment.

15. The water block according to claim 10, wherein the base plate is comprised of a base segment, the bottom surface is formed on outside of the base segment, a bottom end of the through opening is sealed by the base segment, and each fin is respectively attached to an internal surface of the through opening.

16. The water block according to claim 9, further comprising a plurality of heat dissipation fins, and the fins being formed on top of the vapor chamber and arranged at interval.

17. The water block according to claim 9, wherein an annular insert groove is formed on top of the vapor chamber and a bottom edge of the cover is correspondingly embedded in the annular insert groove.

18. The water block according to claim 9, further comprising an inlet tube and at least one outlet tube, wherein the inlet tube is correspondingly connected to the water inlet, and the outlet tube is correspondingly connected to the water outlet.

19. The water block according to claim 18, further comprising a spacer plate, the spacer plate being clipped between a top end of each fin and the cover, and a fluid channel being formed on the spacer plate corresponding to the inlet tube.
